(19) United States
(12) Patent Application Publication
(10) Pub. No.: US 2003/0192586 A1
(43) Pub. Date: Oct. 16, 2003

(54) Space photovoltaic power generation system, portable small power electronic machine, reception antenna apparatus, and electric power system

(75) Inventors: Kazuyuki Takada, Tokyo (JP); Hiroyuki Satou, Tokyo (JP); Izumi Mikami, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/271,527

(22) Filed: Oct. 17, 2002

(30) Foreign Application Priority Data
Apr. 15, 2002 (JP) 2002-111971

(51) Int. Cl. H01L 31/00

(52) U.S. Cl. 136/292; 136/244

(57) ABSTRACT

A power generation satellite converts electric energy generated from sunlight into a microwave and spreads and applies the microwave through a power transmission antenna of the power generation satellite to any desired area widely on earth. The beam width of the microwave is determined by the aperture area of the power transmission antenna placed in the power generation satellite. To spread and apply the microwave to a wide area, the power transmission antenna provided in the power generation satellite need not be a very large antenna having a diameter of several km or more like a power generation satellite power transmission antenna in a space photovoltaic power generation system in a related art.

### BACKGROUND OF THE INVENTION

1. Field of the Invention

This invention relates to a space photovoltaic power generation system wherein sunlight is received and electric power is generated in space and generated DC electric power is transmitted by a microwave through space, is received at a microwave reception antenna (commonly called rectenna), and is converted into DC power for use, and a portable small power electronic machine for obtaining drive power from the space photovoltaic power generation system.

2. Description of the Related Art

The power generation systems using sunlight include a solar battery as a small power generation system, a solar photovoltaic panel installed on a building, intended for home use, and the like. The ground-based photovoltaic power generation is not always efficient because of attenuation of sunlight caused by the atmosphere and shade and light in the night and day on principle. In photovoltaic power generation in space, a solar photovoltaic panel attached to an artificial satellite is well known and the artificial satellite generates electric power required for observation, communications, etc., for satellite's own use and achieves its mission. In any mode, electric power energy generated by the solar battery connected to a specific machine by a cable is used by the specific machine.

On the other hand, a system for receiving sunlight and generating power in space and transmitting to a specific location, for example, a specific point on earth or in space has been researched and developed vigorously receiving support of development of the communication technologies, the construction technologies of large-scaled space structures, and the like based on the result of the recent space development. As an example of such a space photovoltaic power generation system, a system is designed wherein one very large power generation satellite or a plurality of small-scaled and medium-scaled power generation satellites are placed in space and sunlight is gathered and is converted into electric energy in each power generation satellite and then a microwave generated from the electric energy is transmitted to an electric power base on the ground, etc., and is intensively received and rectified at a microwave reception antenna (rectenna) provided in the electric power base to generate DC power and the DC power is supplied to an existing commercial power network. Drive power of electronic machines including a portable electronic machine in related art is obtained from an existing commercial power network as a general rule; particularly as for the portable electronic machine, to obtain drive power, the portable electronic machine must be connected to the existing commercial power network for charging, etc., and has a halfway structure concerning portability. Some portable electronic machines use a storage battery of chemical cells, etc., but can be driven only within the time period during which the electric power stored in the storage battery exists, and have a structure for the user to always have to consider the remaining amount of the electric power.

FIG. 1 is a conceptual drawing to show the general configuration of a power generation satellite in a space photovoltaic power generation system in a related art and the system.

The general configuration and the mechanism of a space photovoltaic power generation system in a related art will be discussed with reference to FIG. 1. In FIG. 1, numeral 1 denotes a power generation satellite for generating electric energy from sunlight in space and generating a microwave from the electric energy and transmitting the microwave. FIG. 1 shows a configuration example containing only one power generation satellite 1, but the power generation satellite 1 may be a power generation satellite group consisting of a plurality of power generation satellites. Numeral 2 denotes a reception antenna (rectenna) of an electric power base for receiving the microwave from the power generation satellite 1 and numeral 3 denotes an electric power base for generating DC power from the received microwave. Numeral 4 denotes a power transmission cable for transmitting the DC power generated at the electric power base 3 to an existing electric power network.

In the space photovoltaic power generation system in the related art, the power generation satellite 1 converts electric energy generated from sunlight into a microwave and transmits the microwave to the rectenna 2 of the electric power base 3 and the electric power base 3 converts the received microwave into DC power and transmits the DC power to the existing electric power network over the power transmission cable 4. The electric power base 3 is placed not only on earth, but also on the surface of the moon, in space plant facilities, etc., for example, in space in some cases. Since the beam width of the microwave transmitted with its phase adjusted in the power generation satellite 1 is determined by the aperture area of the power transmission antenna placed on the power generation satellite 1, as the aperture area of the power transmission antenna of the power generation satellite 1 is enlarged, the beam width of the transmission microwave can be narrowed and the aperture area of the rectenna 2 can be lessened comparatively. However, to install the electric power base on earth, it is predicted that the diameter of the rectenna will reach several to ten and several km although the aperture area of the rectenna 2 can be lessened comparatively because the distance between the power generation satellite 1 and the electric power base 3 is large. At the same time, to realize the above-mentioned rectenna diameter, it is considered that the power transmission antenna diameter of the power generation satellite 1 becomes several km or more.

Thus, in the space photovoltaic power generation system in the related art, as the power transmission antenna and the power reception antenna (rectenna), very large antennas not yet manufactured are required. It is considered that it is difficult to manufacture the power transmission antenna and the power reception antenna under present circumstances; this is a large problem for realizing space photovoltaic power generation.

FIG. 5 is a block diagram of a portable small power electronic machine driven by an electric power system in a related art.

The configuration of a portable small power electronic machine driven by an electric power system in a related art will be discussed with reference to FIG. 5. In FIG. 5, numeral 10 denotes an existing commercial power network, numeral 11 denotes a battery for converting AC power provided from the existing commercial power network 10 into DC power for charging, and numeral 12 denotes a mission section of the electronic machine.

In the portable small power electronic machine driven by the electric power system in the related art, the battery 11 is charged as drive power in the form of DC power from the existing commercial power network 10 and using the DC power provided by the battery 11, the mission to be served by the electronic machine is achieved by the mission section 12. An electronic machine is also available in which a storage battery is built in place of the battery 11 for driving the mission section 12 independently of the existing commercial power network 10.

Such a portable small power electronic machine in the related art has a disadvantage that it can be driven only where the existing commercial power network 10 exists or only within the time during which the electric power stored in the storage battery exists.

### SUMMARY OF THE INVENTION

It is therefore an object of the invention to provide a space photovoltaic power generation system not requiring a terrestrial electric power base including a large-scaled rectenna having a diameter of several km to ten and several km. Namely, a space photovoltaic power generation system wherein a microwave transmitted from a power transmission antenna in space is spread and applied to a comparatively wide area of a power consumption area of a city. Enough electric power as required can be obtained through an indefinite number of small-scaled rectennas discretely existing without installing any terrestrial electric power base in the wide area to which the microwave is applied.

According to a first aspect of the invention, there is provided a space photovoltaic power generation system having a space photovoltaic power generation satellite and a reception antenna. The space photovoltaic power generation satellite gathers sunlight in space, generates electric energy from the gathered sunlight, generates a microwave from the generated electric energy, and transmittes the microwave through a transmission antenna. The reception antenna receives the transmitted microwave and converts the received microwave into DC power to be a power source. The space photovoltaic power generation satellite spreads and applies the microwave to a power consumption area.

According to a second aspect of the invention, there is provided a portable small power electronic machine having a microwave reception antenna, a rectification circuit, and a power combining section. The microwave reception antenna receives a microwave transmitted from a space photovolatic power generation satellite. The rectification circuit converts and rectifies the microwave into DC power. The power combining section which combines the DC power.

According to a third aspect of the invention, a reception antenna apparatus having a reception antenna, a rectification circuit, and a power supply interface. The reception antenna receives a microwave spread and applied from a space photovoltaic power generation satellite to a power consumption area. The rectification circuit converts and rectifies the microwave received through the reception antenna into DC power. The power supply interface supplies the electric power output from the rectification circuit as drive power of a portable small power electronic machine.

According to a fourth aspect of the invention, there is provided an electric power system having a power transmission base and a reception antenna. The power transmission base converts electric energy into a microwave and transmits the microwave through a transmission antenna. The reception antenna receives the transmitted microwave and converts the received microwave into DC power to be a power source. The power transmission base spreads and applies the microwave to a power consumption area.

### BRIEF DESCRIPTION OF THE DRAWINGS

In the accompanying drawings:

FIG. 1 is a conceptual drawing to show the general configuration of a power generation satellite in a space photovoltaic power generation system in a related art and the system;

FIG. 2 is a conceptual drawing to show the configuration of a space photovoltaic power generation system according to a first embodiment of the invention;

FIG. 3 is a schematic drawing to show an example of area formation wherein a microwave is spread from a power generation satellite according to the first embodiment of the invention and is applied directly to a power consumption area of a city, a residential area, etc., and electric power can be gotten at discreetly placed rectennas;

FIG. 4 is a schematic drawing to show an example of area formation wherein a microwave is spread from the power generation satellite according to the first embodiment of the invention and is applied directly to a power consumption area of a city, a residential area, etc., and electric power can be gotten at discreetly placed rectennas;

FIG. 5 is a block diagram of a portable small power electronic machine driven by an electric power system in a related art;

FIG. 6 is a block diagram of a portable small power electronic machine according to a second embodiment of the invention;

FIG. 7 is a drawing to show the range of electronic machines driven by a microwave transmitted from a power generation satellite according to second and third embodiments of the invention;

FIG. 8 is a diagram to show the configuration of a portable small power electronic machine containing a rectenna array comprising a plurality of rectenna elements connected in series, each rectenna element consisting of a reception antenna and a rectification circuit, and a power combining section in a cabinet according to a third embodiment of the invention;

FIG. 9 is a diagram of the configuration of a reception antenna apparatus according to a fourth embodiment of the invention;

FIG. 10 is a diagram of the configuration of a reception antenna apparatus according to a fifth embodiment of the invention; and

FIG. 11 is a diagram of the configuration of an electric power system according to a sixth embodiment of the invention.

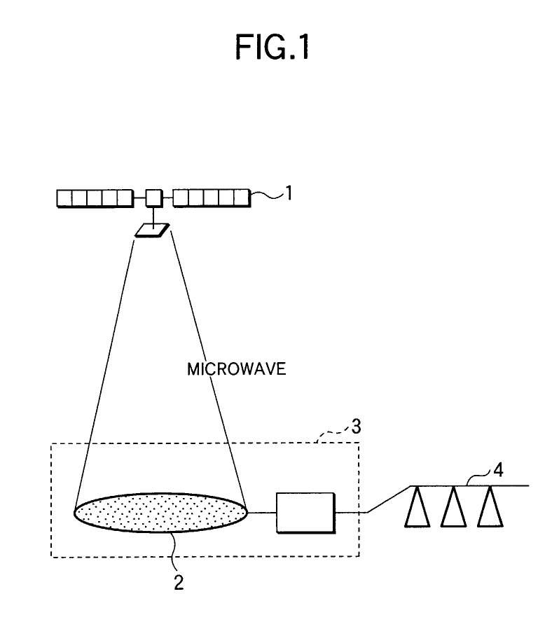

### DETAILED DESCRIPTION OF THE PREFERRED EMBODIMENTS

First Embodiment.

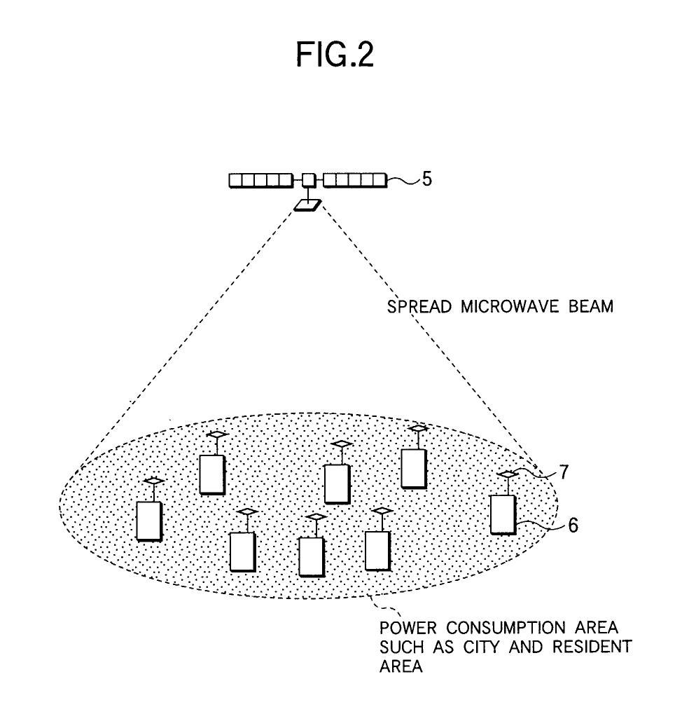

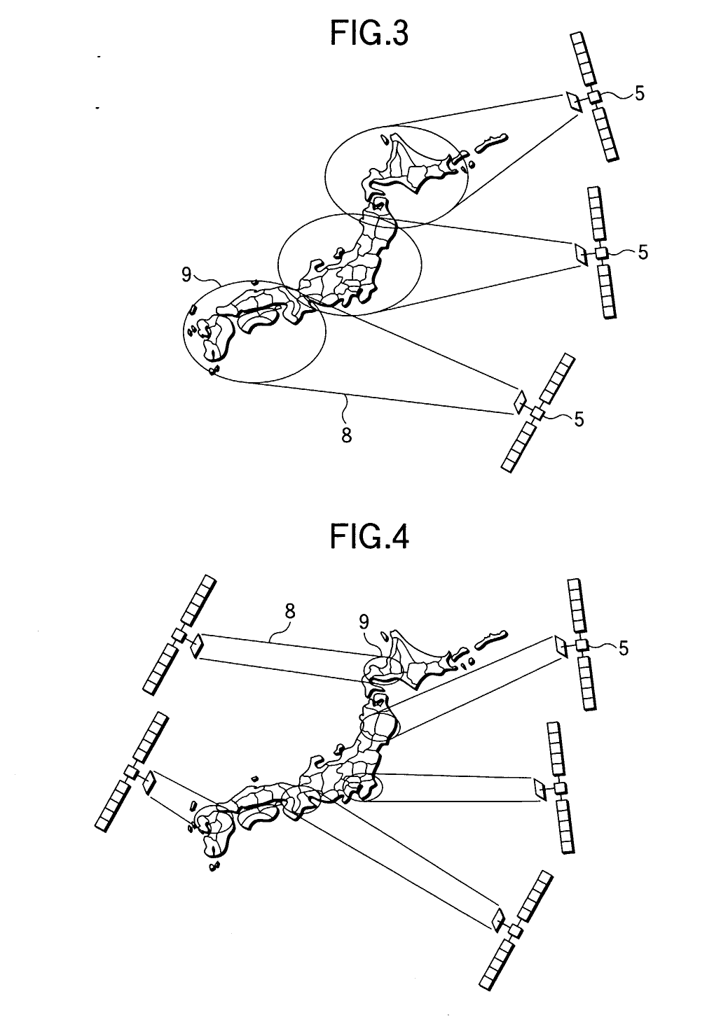

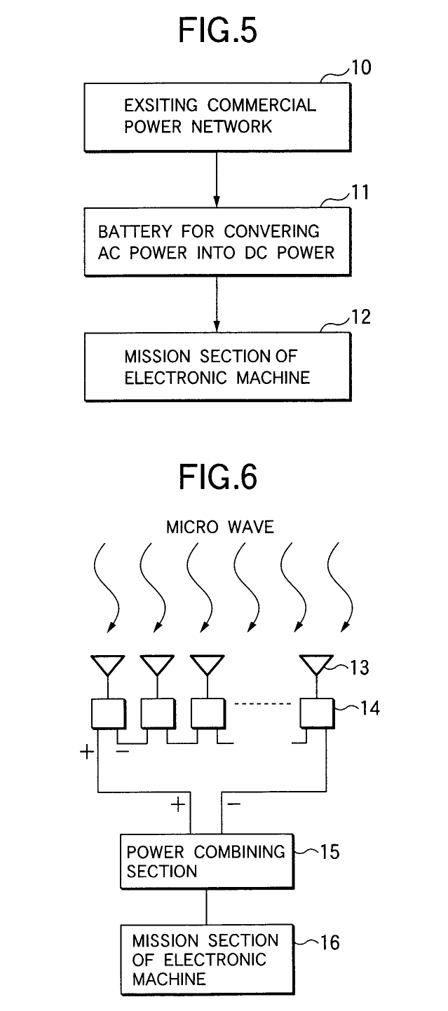

A space photovoltaic power generation system according to a first embodiment of the invention will be discussed with reference to FIGS. 2 to 4. FIG. 2 is a conceptual drawing to show the configuration of the space photovoltaic power generation system according to the first embodiment of the invention. FIGS. 3 and 4 are schematic drawings of area formation wherein a microwave is spread from a power generation satellite and is applied directly to a power consumption area of a city, a residential area, etc., and electric power can be gotten at discretely placed rectennas.

Next, the general configuration and the mechanism of a space photovoltaic power generation system according to the invention will be discussed with reference to FIG. 2. In FIG. 2, numeral 5 denotes a power generation satellite for generating electric energy from sunlight in space and generating a microwave from the electric energy and transmitting the microwave. FIG. 2 shows a configuration example containing only one power generation satellite 5, but the power generation satellite 5 may be a power generation satellite group consisting of a plurality of power generation satellites. Numeral 6 denotes a portable small power electronic machine and numeral 7 denotes a small-sized rectenna array for supplying drive power to the portable small power electronic machine. The portable small power electronic machines 6 and the rectenna arrays 7 are placed discretely and need not be placed at fixed positions and may be changed in position at any time like mobile telephones, etc.

In the space photovoltaic power generation system according to the invention, the power generation satellite 5 converts electric energy generated from sunlight into a microwave and spreads and applies the microwave through a power transmission antenna of the power generation satellite 5 to any desired area widely on earth. Since the beam width of the microwave is determined by the aperture area of the power transmission antenna placed on the power generation satellite 5, in order to spread and apply the microwave to a wide area, the power transmission antenna provided on the power generation satellite 5 need not be a very large antenna having a diameter of several km or more like the power transmission antenna of the power generation satellite in the space photovoltaic power generation system in the related art. In a comparatively wide area of a power consumption area of a city, etc., to which the microwave is spread and applied, the microwave is converted into DC power through the small-sized rectenna array 7 and the portable small power electronic machines 6 can be driven directly by the DC power or indirectly by stable DC power provided by charging a battery with that CD power. In the space photovoltaic power generation system according to the invention, a microwave is spread and applied to any desired area of a comparatively wide area of a power consumption area of a city, etc., so that it is not necessary to install an electric power base including a large-scaled rectenna on the ground.

As described above, in the space photovoltaic power generation system according to the invention, unlike the space photovoltaic power generation system in the related art, it is not necessary to build a very large power transmission antenna provided on a power generation satellite having a diameter reaching several km or a very large rectenna provided in a terrestrial electric power base having a diameter reaching several to ten and several km, and feasibility is enhanced. The power transmission antenna provided on the power generation satellite 5 may be a very large power transmission antenna examined previously if it can spread and apply a microwave to a wide area.

The space photovoltaic power generation system according to the invention has another advantage that it spreads a microwave and applies the spread microwave to any desired area on the ground and thus can circumvent the adverse effect on the environment such as ionosphere destruction caused by concentration of microwave.

According to the space photovoltaic power generation system according to the invention, in the power consumption area of a city, etc., to which a microwave is spread and applied, not only the portable small power electronic machine 6, but also an electronic machine if it is driven by electric power that can be obtained through the small rectenna array 7 can obtain drive power as desired; there is a possibility that the system can replace chemical cells or a battery used as the drive power supply of the small power electronic machine in the related art, and an electronic machine system in which the user is not worried about shortage of supply power or the remaining amount of supply power can be constructed.

Next, formation of areas wherein a microwave from a power generation satellite is spread and applied directly to a power consumption area of a city, a residential area, etc., and electric power can be gotten through rectennas discretely placed is shown in schematic drawings of FIGS. 3 and 4 by taking the case where the areas are created in the Japanese Islands as an example. In FIG. 3, numeral 5 denotes the above-described power generation satellite, numeral 8 denotes a microwave beam spread and applied from the power generation satellite 5, and numeral 9 denotes an area to which the microwave beam 8 is applied.

One power generation satellite can supply a microwave beam to all areas of the Japanese Islands, in which case an enormous power generation capability is demanded of the power generation satellite. Therefore, to decrease the power generation capability per power generation satellite and enhance feasibility, it is preferable that a plurality of power generation satellites 5 share the areas of the Japanese Islands as shown in FIG. 3.

On the other hand, to transmit microwaves as shown in FIG. 3, it is feared that the microwaves transmitted to mountainous areas and forests may be wasted. Then, as shown in FIG. 4, it is also possible that each area in which power supply demand of a microwave is particularly expected, such as a city, is set to an area wherein electric power can be gotten as a microwave is applied to a wide area. In this case, applying electric power to mountainous areas and forests is eliminated and the efficiency of the system is enhanced, but the number of the power generation satellites is increased.

Second Embodiment.

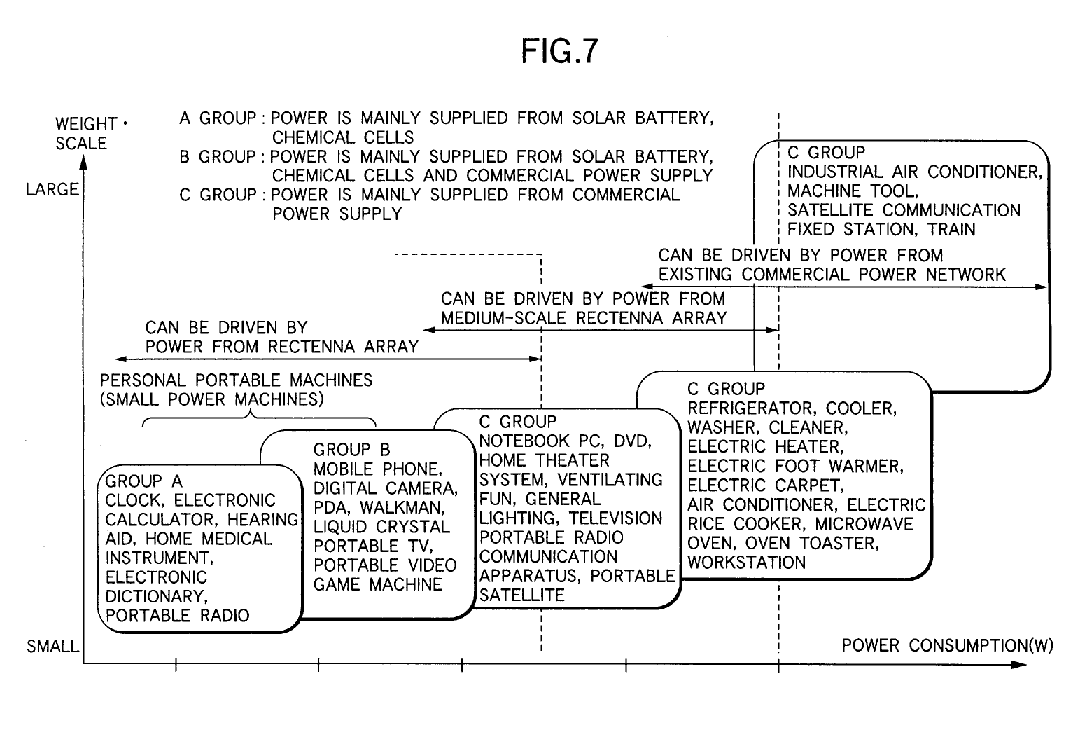

A portable small power electronic machine according to a second embodiment of the invention will be discussed with reference to FIGS. 6 to 7. FIG. 6 is a block diagram of a portable small power electronic machine according to the second embodiment of the invention. FIG. 7 is a drawing to show the range of electronic machines driven by a microwave transmitted from a power generation satellite according to the second embodiment of the invention.

The configuration of a portable small power electronic machine according to the invention that can overcome the disadvantage in the related art will be discussed with reference to FIG. 6. In FIG. 6, numeral 13 denotes reception antenna sections for receiving a microwave transmitted from a power generation satellite. Numeral 14 denotes rectification circuit sections for converting the microwave received through the reception antenna sections 13 into DC power. Numeral 15 denotes a power combining section for combining DC power provided by the rectification circuit sections 14. Numeral 16 denotes a mission section of the electronic machine. The reception antenna section 13 and the rectification circuit section 14 are combined into a rectenna element and a plurality of rectenna elements are connected in series, thereby forming a rectenna array. The power combining section 15 may contain a charging section for stabilizing the combined DC power.

The portable small power electronic machine according to the invention receives the microwave transmitted from the power generation satellite at the reception antenna 13 and converts the received microwave into DC power by the rectification circuit 14. The power combining section 15 combines the DC power provided by the plurality of reception antennas 13 and the plurality of rectification circuits 14 and using the combined power, the mission section 16 executes the electronic: machine mission.

The portable small power electronic machine of the invention described with reference to FIG. 6 converts the microwave transmitted from the power generation satellite into DC power as drive power through the reception antennas 13, the rectification circuits 14, and the power combining section 15 in the area of a power consumption area, etc., to which the microwave is spread and applied by the space photovoltaic power generation system according to the first embodiment. The user can use the portable small power electronic machine of the invention without being aware of the remaining amount of the supply power if the user uses the electronic machine in the space wherein the microwave is spread and applied to the area of a power consumption area, etc.

The portable small power electronic machine of the invention may have no portability if it is a machine driven by DC power provided from the microwave transmitted from the power generation satellite. FIG. 7 shows classification of the small power electronic machines that can be driven in the invention. According to FIG. 7, not only the small power electronic machines driven by power from chemical cells or a battery, but also the small power electronic machines driven by power from the existing commercial power network rather than chemical cells or a battery can be driven by DC power provided from the microwave transmitted from the power generation satellite.

Third Embodiment.

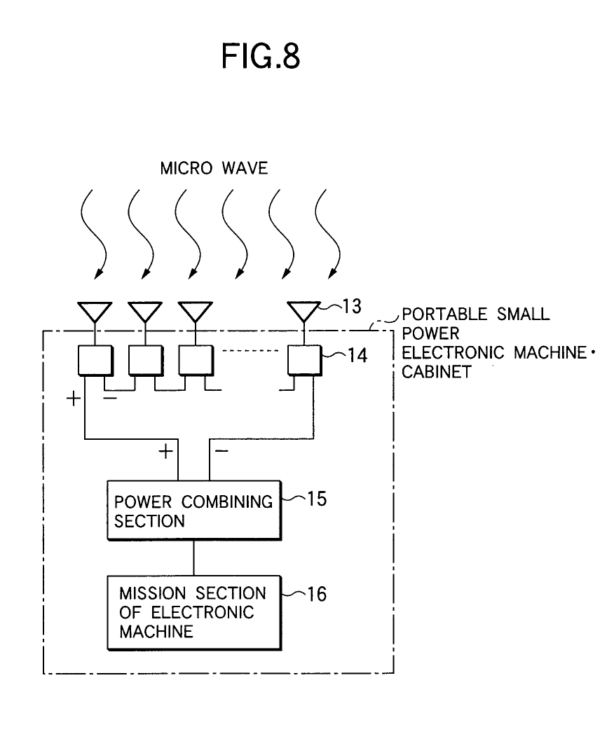

A portable small power electronic machine according to a third embodiment of the invention will be discussed with reference to FIGS. 7 and 8. FIG. 8 shows the configuration of the portable small power electronic machine containing a rectenna array including a plurality of rectenna elements connected in series, each rectenna element having a reception antenna 13 and a rectification circuit 14, and a power combining section 15 in a cabinet according to the third embodiment of the invention.

The portable small power electronic machine of the invention having the configuration shown in FIG. 8 converts the transmitted microwave into DC power as drive power through the reception antennas 13, the rectification circuits 14, and the power combining section 15 in the space of a power consumption area, etc., to which the microwave is spread and applied by the space photovoltaic power generation system according to the first embodiment. The user can use the portable small power electronic machine of the invention without being aware of the remaining amount of the supply power of a battery or a storage battery if the user uses the electronic machine in the space wherein the microwave is spread and applied to the area of a power consumption area, etc. As the rectenna array and the power combining section 15 replace the power supply section of the portable small power electronic machine in the related art, the portability of the portable small power electronic machine of the invention is improved.

The portable small power electronic machine of the invention may have no portability if it is a machine driven by DC power provided from the microwave transmitted from the power generation satellite. FIG. 7 shows classification of the small power electronic machines that can be driven in the invention. According to FIG. 7, not only the small power electronic machines driven by power from chemical cells or a battery, but also the small power electronic machines driven by power from the existing commercial power network rather than chemical cells or a battery can be driven by DC power provided from the microwave transmitted from the power generation satellite.

Fourth Embodiment.

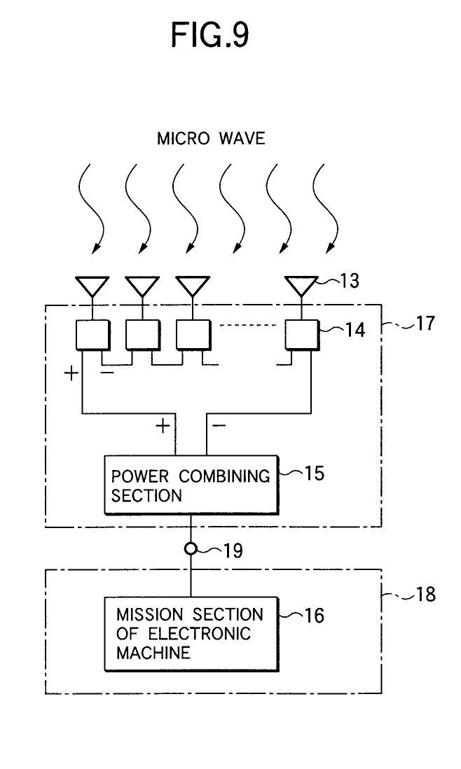

A reception antenna apparatus according to a fourth embodiment of the invention will be discussed with reference to FIG. 9. In FIG. 9, numeral 13 denotes a reception antenna for receiving a microwave transmitted from a power generation satellite. Numeral 14 denotes a rectification circuit section for converting the microwave received through the reception antenna section 13 into DC power. Numeral 15 denotes a power combining section for combining DC power provided by the rectification circuit section 14. Numeral 16 denotes a mission section of the electronic machine. Numeral 17 denotes a reception antenna apparatus including a plurality of reception antennas 13, a plurality of rectification circuits 14, and the power combining section 15. Numeral 18 denotes a portable small power electronic machine. Numeral 19 denotes a power supply interface for supplying electric power from the reception antenna apparatus 17 to the portable small power electronic machine 18. The reception antenna section 13 and the rectification circuit section 14 are combined into a rectenna element and a plurality of rectenna elements are connected in series, thereby forming a rectenna array. The power combining section 15 may contain a charging section for stabilizing the combined DC power.

The microwave transmitted from the power generation satellite is received at the reception antenna 13 and the received microwave is converted into DC power by the rectification circuit 14. The power combining section 15 combines the DC power provided by the plurality of reception antennas 13 and the plurality of rectification circuits 14 and supplies the power through the power supply interface 19 to the portable small power electronic machine 18. The power supply interface 19 makes it possible to connect and disconnect the reception antenna apparatus 17 and the portable small power electronic machine 18. Any electronic machine, if it can be driven by DC power generated by the reception antenna apparatus 17, can be connected to the power supply interface 19 to obtain drive power regardless of whether or not the electronic machine has portability.

Possible application examples of the reception antenna apparatus 17 are a wearable clothing-contained rectenna comprising the reception antennas 13, the rectification circuits 14, the power combining section 15, and the reception antenna apparatus 17 placed in clothing and a roof, etc., of a simple frame house of a tent, etc., as a rectenna. It is also possible to build the rectenna array according to the invention in the outer or inner surface of a large- or medium-scaled structure of a building, a house, a road, etc., or a small-scaled structure of a desk, a shelf, an automobile body, etc., although portability is not provided. Fifth embodiment.

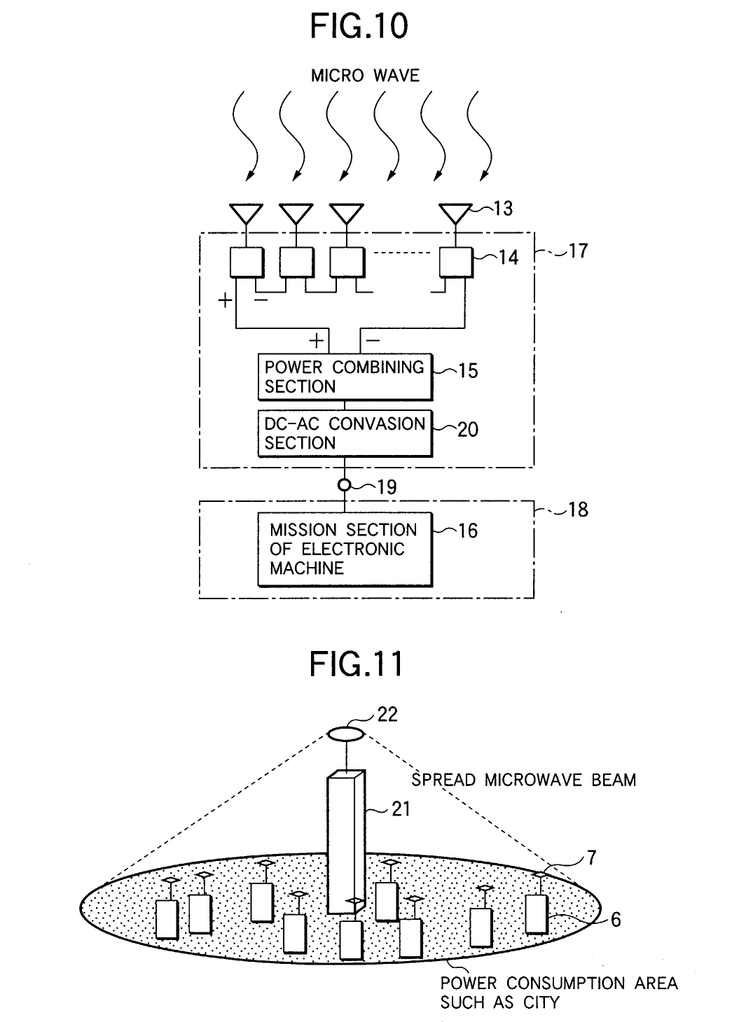

A reception antenna apparatus according to a fifth embodiment of the invention will be discussed with reference to FIG. 10. FIG. 10 is a conceptual drawing of the reception antenna apparatus according to the fifth embodiment of the invention. In FIG. 10, numeral 13 denotes a reception antenna for receiving a microwave transmitted from a power generation satellite. Numeral 14 denotes a rectification circuit section for converting the microwave received through the reception antenna section 13 into DC power. Numeral 15 denotes a power combining section for combining DC power provided by the rectification circuit section 14. Numeral 16 denotes a mission section of the electronic machine. Numeral 17 denotes a reception antenna apparatus including a plurality of reception antennas 13, a plurality of rectification circuits 14, and the power combining section 15. Numeral 18 denotes a portable small power electronic machine. Numeral 19 denotes a power supply interface for supplying electric power from the reception antenna apparatus 17 to the portable small power electronic machine 18. Numeral 20 denotes a DC-AC conversion section for converting the DC power provided by the power combining section 15 into AC power. The reception antenna section 13 and the rectification circuit section 14 are combined into a rectenna element and a plurality of rectenna elements are connected in series, thereby forming a rectenna array. The power combining section 15 may contain a charging section for stabilizing the combined DC power.

The microwave transmitted from the power generation satellite is received at the reception antenna 13 and the received microwave is converted into DC power by the rectification circuit 14. The power combining section 15 combines the DC power provided by a plurality of reception antennas 13 and a plurality of rectification circuits 14. The DC-AC conversion section 20 converts the resultant DC power into AC power. The provided AC power is supplied through the power supply interface 19 to the portable small power electronic machine 18. The power supply interface 19 makes it possible to connect and disconnect the reception antenna apparatus 17 and the portable small power electronic machine 18. Any electronic machine, if it can be driven by AC power generated by the reception antenna apparatus 17, can be connected to the power supply interface 19 to obtain drive power regardless of whether or not the electronic machine has portability.

Most of the current electronic machines are driven by AC power. Therefore, the DC power provided through the rectenna array from the microwave transmitted from the power generation satellite is converted into AC power, whereby every electric machine existing at present can be driven through the rectenna antenna according to the invention.

To drive the current electronic machines through the rectenna antenna according to the invention as described above, a power supply terminal adopted for existing electric power systems (usually, called a wall outlet, a receptacle, etc.,) may be adopted as the terminal form of the power supply interface 19.

A possible application example of the rectenna array according to the fifth embodiment is a system wherein the rectenna array is installed on the roof, a wall, etc., of a simple frame house of a tent, a prefabricated house, etc., and an electric machine can be driven by AC power in the simple frame house. Demands for the rectenna array in camping, as a power supply source in disaster situations, etc., can be expected. It is also possible to build the rectenna array according to the invention in the outer or inner surface of a large- or medium-scaled structure of a building, a house, a road, etc., or a small-scaled structure of a desk, a shelf, an automobile body, etc., although portability is not provided. Sixth embodiment.

An electric power system according to a sixth embodiment of the invention will be discussed with reference to FIG. 11. FIG. 11 is a conceptual drawing to show the configuration of an electric power system according to a sixth embodiment of the invention. In FIG. 11, numeral 6 denotes a portable small power electronic machine. Numeral 7 denotes a small-sized rectenna array for supplying drive power to the portable small power electronic machine. Numeral 21 denotes a power transmission base. Numeral 22 denotes a microwave transmission antenna.

In the electric power system according to the sixth embodiment, the power transmission base 21 generates a microwave by electric power provided from an existing commercial power network or electric power provided by independent electric power generation facilities of solar batteries, a wind turbine generator system, etc., installed in the power transmission base 21 and spreads and applies the generated microwave to a power consumption area of a city, etc., widely from the microwave transmission antenna 22. The power transmission base 21 is placed in the power consumption area as shown in FIG. 11 and in addition, it can also exist outside the power consumption area. A plurality of power transmission bases 21 may exist inside and outside the power consumption area or the power transmission base 21 may be provided with a plurality of microwave transmission antennas 22. In a comparatively wide area of a power consumption area of a city, etc., to which the microwave is spread and applied, the microwave is converted into DC power through the small-sized rectenna array 7 and the portable small power electronic machines 6 can be driven directly by the DC power or indirectly by stable DC power provided by charging a battery with that CD power.

What is claimed is:

1. A space photovoltaic power generation system comprising:
a space photovoltaic power generation satellite, which gathers sunlight in space, generates electric energy from the gathered sunlight, generates a microwave from the generated electric energy, and transmits the microwave through a transmission antenna; and
a reception antenna which receives the transmitted microwave and converts the received microwave into DC power to be a power source,
wherein the space photovoltaic power generation satellite spreads and applies the microwave to a power consumption area.

2. A portable small power electronic machine comprising:
a microwave reception antenna which receives a microwave transmitted from a space photovolatic power generation satellite;
a rectification circuit which converts and rectifies the microwave into DC power; and
a power combining section which combines the DC power.

3. The portable small power electronic machine according to claim 2 further comprising a cabinet,
wherein the microwave reception antenna is a small-sized reception antenna contained in the cabinet.

4. A reception antenna apparatus comprising:
a reception antenna which receives a microwave spread and applied from a space photovoltaic power generation satellite to a power consumption area;
a rectification circuit which converts and rectifies the microwave received through the reception antenna into DC power; and
a power supply interface which supplies the electric power output from the rectification circuit as drive power of a portable small power electronic machine.

5. The reception antenna apparatus according to claim 4, further comprising a DC-AC converter which converts the DC power output from the rectification circuit into AC power,
wherein the power supply interface which supplies the electric power output from the DC-AC converter as the drive power of the portable small power electronic machine instead of the electric power output from the rectification circuit.

6. An electric power system comprising:
a power transmission base which converts electric energy into a microwave and transmits the microwave through a transmission antenna; and
a reception antenna which receives the transmitted microwave and converts the received microwave into DC power to be a power source,
wherein the power transmission base spreads and applies the microwave to a power consumption area.

7. The electric power system according to claim 6, wherein the power transmission base gathers sunlight and generates electric energy from the gathered sunlight
